(19) United States
(12) Patent Application Publication
(10) Pub. No.: US 2026/0013222 A1
(43) Pub. Date: Jan. 8, 2026

(54) INSULATING PLUG IN BACKSIDE POWER DELIVERY NETWORK

(71) Applicant: INTERNATIONAL BUSINESS MACHINES CORPORATION, ARMONK, NY (US)

(72) Inventors: HUIMEI ZHOU, Albany, NY (US); Ruilong Xie, Niskayuna, NY (US); Xiaoming Yang, Clifton Park, NY (US); LEI ZHUANG, Ridgefield, CT (US); Ravikumar Ramachandran, Pleasantville, NY (US); Mahender Kumar, Clifton Park, NY (US); Reinaldo Vega, Mahopac, NY (US)

(21) Appl. No.: 18/762,608

(22) Filed: Jul. 2, 2024

(51) Int. Cl. H01L 27/092; H01L 21/311; H01L 21/3205; H01L 21/768; H01L 23/522; H01L 23/532; H01L 29/06; H01L 29/161; H01L 29/40; H01L 29/423; H01L 29/66; H01L 29/775; H01L 29/786

(52) U.S. Cl. CPC H10D 84/859; H01L 21/31116; H01L 21/76877; H10D 62/107; H10D 62/115; H10D 64/01; H01L 21/32053; H01L 23/5226; H01L 23/53209; H10D 30/014; H10D 30/43; H10D 30/6735; H10D 30/6757; H10D 62/121; H10D 62/832

(57) ABSTRACT

A semiconductor device includes a shallow trench isolation (STI), a first well region connected to the insulating region and the STI on a first side, a second well region connected to the insulating region and the STI on a second side, and a backside contact including an upper portion, a lower portion, and a middle portion connecting the upper portion and the lower portion. A shape and a profile of the insulating region is same as a shape and a profile of the middle portion.

### BACKGROUND

### Technical Field

The present disclosure generally relates to semiconductors, and more particularly, to semiconductors with an insulating plug in backside power delivery network structure, and methods of creation thereof.

### Description of Related Art

The relentless miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. The evolution towards system-on-chip architectures integrates various functionalities, including processing and sensing, on one chip. Delivering power through the backside of the wafer reduces congestion on the frontside, which is crowded with interconnects and signal lines, enhancing power integrity and reducing noise. Thermal management benefits from the backside power delivery network (BSPDN) by providing an additional pathway for heat dissipation. The backside of the wafer helps spread and dissipate heat more effectively, preventing hot spots and improving the device's reliability and longevity.

The BSPDN also allows for increased device density. With power delivery handled by the backside, the frontside is freed up for more interconnects and active components, enabling a higher density of transistors and other elements. Electromigration, which is the gradual movement of metal atoms due to high current densities, can lead to interconnect failure. The BSPDN reduces the current density in frontside interconnects, alleviating stress on the frontside metal layers and enhancing the device's reliability. IR drop, the voltage drop due to the resistance of power delivery paths, can affect device performance.

The BSPDN provides shorter and more direct paths for power delivery, reducing overall resistance and ensuring critical components receive stable power. The BSPDN is compatible with advanced packaging technologies such as 3D stacking and chiplet architectures. Using the backside for power delivery allows these techniques to achieve better performance and integration, supporting the evolution of semiconductor technology toward more compact and powerful solutions.

### SUMMARY

According to an embodiment, a semiconductor device includes a shallow trench isolation (STI), a first well region connected to the insulating region and the STI on a first side, a second well region connected to the insulating region and the STI on a second side, and a backside contact including an upper portion, a lower portion, and a middle portion connecting the upper portion and the lower portion. A shape and a profile of the insulating region is same as a shape and a profile of the middle portion.

In one embodiment, a width of the insulating region is smaller than a width of the STI.

In one embodiment, the semiconductor device includes an insulating layer horizontally extended below the semiconductor device. The insulating region is above and directly connected to the insulating layer.

In one embodiment, a width of the STI has a first end and a second end, a width of the insulating region has a third end and a fourth end, the insulating region is centrally aligned with the STI, and a first distance from the first end to the third end is equal to a second distance from the second end to the fourth end.

In one embodiment, the middle portion is surrounded by two adjacent well regions doped with different types of dopants.

In one embodiment, the middle portion is surrounded by two adjacent well regions doped with a same type of dopant.

In one embodiment, the first well region and the second well region are doped with a same type of dopant.

In one embodiment, the first well region and the second doped region are doped with different types of dopants.

In one embodiment, the semiconductor device includes a conductive layer covering the lower portion, a silicide layer covering the conductive layer, and a doped layer covering the silicide layer.

In one embodiment, the conductive layer is a metal layer, the silicide layer includes at least one of: a titanium silicide layer, a nickel silicide layer, and a cobalt silicide layer, and the doped layer includes a silicon germanium layer epitaxially grown over the silicide layer.

In one embodiment, the semiconductor device includes a liner layer between the lower portion and the conductor layer, wherein the liner layer includes titanium nitride.

According to an embodiment, a method for fabrication of a semiconductor device, includes forming a shallow trench isolation (STI), forming an insulating region below the STI, forming a first well region connected to the insulating region and the STI on a first side, forming a second well region connected to the insulating region and the STI on a second side, and forming a backside contact comprising an upper portion, a lower portion, and a middle portion connecting the upper portion and the lower portion. A shape and a profile of the insulating region is same as a shape and a profile of the middle portion.

In one embodiment, the method includes forming an insulating layer horizontally extended below the semiconductor device, and establishing a direct connection between the insulating region and the insulating layer.

In one embodiment, the method incudes surrounding the middle portion by two adjacent well regions doped with different types of dopants.

In one embodiment, the method includes surrounding the middle portion by two adjacent well regions doped with a same type of dopant.

In one embodiment, the method includes doping he first well region and the second well region with a same type of dopant.

In one embodiment, the method includes doping the first well region and the second doped region with different types of dopants.

In one embodiment, the method includes forming a conductive layer covering the lower portion, forming a silicide layer covering the conductive layer, and forming a doped layer covering the silicide layer.

In one embodiment, the method includes forming a liner layer between the lower portion and the conductor layer.

According to an embodiment, a semiconductor device includes a shallow trench isolation (STI), an insulating region below the STI, a first well region connected to the insulating region and the STI on a first side, a second well region connected to the insulating region and the STI on a second side, and an insulating layer horizontally extended below and directly connected to the insulating layer. A width of the STI has a first end and a second end, a width of the insulating region has a third end and a fourth end, the insulating region is centrally aligned with the STI, and a first distance from the first end to the third end is equal to a second distance from the second end to the fourth end.

In one embodiment, the semiconductor device includes a backside contact including an upper portion, a lower portion, and a middle portion connecting the upper portion and the lower portion. A shape and a profile of the insulating region is same as a shape and a profile of the middle portion.

In one embodiment, the semiconductor device includes a conductive layer covering the lower portion, a silicide layer covering the conductive layer, and a doped layer covering the silicide layer.

In one embodiment, the conductive layer is a metallic layer, the silicide layer includes at least one of: a titanium silicide layer, a nickel silicide layer, and a cobalt silicide layer, and the doped layer includes a silicon germanium layer epitaxially grown over the silicide layer.

In one embodiment, the semiconductor device includes a liner layer between the lower portion and the conductor layer, wherein the liner layer includes titanium nitride.

In one embodiment, the conductive layer is made of a same material as the lower portion.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates a semiconductor device, in accordance with some embodiments.

FIG. 2 illustrates a semiconductor device after the formation of a liner, in accordance with some embodiments.

FIG. 3 illustrates a semiconductor device after the etching of the semiconductor device, in accordance with some embodiments.

FIG. 4 illustrates a semiconductor device after the filling the etched regions, in accordance with some embodiments.

FIG. 5 illustrates a semiconductor device after the removal of the liner, in accordance with some embodiments.

FIG. 6 illustrates a semiconductor device after the formation of the shallow trench isolation, in accordance with some embodiments

FIG. 7 illustrates a semiconductor device after the formation of the gates, in accordance with some embodiments.

FIG. 8 illustrates a semiconductor device after the gate region metallization, in accordance with some embodiments.

FIG. 9 illustrates a semiconductor device after the formation of the frontside contact, in accordance with some embodiments.

FIG. 10 illustrates a semiconductor device after the back end of line processes, in accordance with some embodiments.

FIG. 11 illustrates a semiconductor device after the recession of the backside contact, in accordance with some embodiments.

FIG. 12 illustrates a semiconductor device after the recession of the insulating layer, in accordance with some embodiments.

FIG. 13 illustrates a semiconductor device after the patterning of the insulating region, in accordance with some embodiments.

FIG. 14 illustrates a semiconductor device after the formation of the backside contact, in accordance with some embodiments.

FIG. 15 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

In semiconductor device fabrication, the overlay of the backside contact remains an issue as devices continue to scale down in size. Overlay in a semiconductor device refers to the precise alignment of different layers during the fabrication process. As semiconductor devices continue to scale down, achieving accurate overlay becomes increasingly challenging. This alignment is important because even minor misalignments can lead to significant issues. Misalignment in overlay can result in increased electrical resistance. When layers are not aligned, the intended conductive paths may become longer or interrupted, causing higher resistance. This increase in resistance can degrade the device's performance, leading to slower signal transmission and higher power consumption. Furthermore, overlay errors can cause defects in the electrical connections between layers. Inaccurate alignment can create open circuits or short circuits, where connections either fail to form or connect unintended areas. These defects can lead to device failure, reducing the yield of functional devices from a wafer and increasing manufacturing costs.

Overlay inaccuracies can also impact the overall reliability of the semiconductor device. Misaligned layers may introduce mechanical stress and weaken the structural integrity of the device. The stress can cause cracks or delamination, especially under thermal cycling or operational conditions, leading to premature device failure. In semiconductor nodes, where feature sizes are extremely small, the margin for error in overlay alignment is minimal. The challenges of maintaining accurate overlay become more pronounced, demanding more sophisticated lithography and alignment techniques. Inadequate overlay control can thus hinder the advancement of semiconductor technology, as it limits the ability to scale down device dimensions while maintaining performance and reliability.

The isolation of backside vias presents an additional challenge in the implementation of backside power delivery networks. Backside vias provide electrical connections through the substrate, enabling efficient power distribution across the semiconductor device. However, as devices scale down, ensuring adequate isolation between these vias becomes more complex. Inadequate isolation can result in electrical crosstalk, leakage currents, and interference between different circuit elements, which can significantly degrade the overall performance and reliability of the device. Effective backside via isolation is crucial for maintaining signal integrity and ensuring the robust operation of the backside power delivery network in advanced semiconductor technologies.

In view of the above considerations, disclosed is a semiconductor device with an insulating region in the backside of the semiconductor device. The disclosed semiconductor device features a structure that incorporates both a STI plug and an isolated backside via simultaneously, all achieved without the need for an additional mask during the fabrication process. This approach simplifies the manufacturing steps and reduces complexity, making it more cost-effective and efficient.

The STI plug form within the semiconductor device ensures robust electrical isolation between adjacent components. This isolation prevents electrical crosstalk and interference, which can degrade the performance of the device. By integrating the STI plug with the isolated backside via, the device maintains isolation characteristics, which is particularly important as device dimensions continue to shrink in advanced semiconductor technologies. The isolated backside via provides a reliable and efficient pathway for electrical connections from the frontside to the backside of the semiconductor wafer. The via can help the power delivery network, allowing for effective distribution of power across different regions of the semiconductor device. The isolation of the backside via ensures that there is no unintended electrical interaction between the via and other components of the device, thereby maintaining signal integrity and reducing the risk of leakage currents.

Moreover, the design effectively addresses the challenges associated with backside contact overlay. In traditional semiconductor fabrication, aligning backside contacts with the frontside features can be challenging, leading to potential misalignment and associated performance issues. The disclosed semiconductor device's design inherently ensures that the backside contact overlay is accurately aligned with the frontside features, thereby eliminating the risk of misalignment. This precise alignment is achieved without requiring additional masks or complex alignment procedures, further simplifying the manufacturing process.

The incorporation of the STI plug and the isolated backside via without additional masking steps simplifies the overall fabrication process, reducing both time and costs associated with manufacturing. The streamlined process also enhances the yield and reliability of the semiconductor devices produced, making it a highly efficient solution for advanced semiconductor applications.

Accordingly, the teachings herein provide methods and systems of semiconductor device formation with an insulating region in the backside power delivery network. The techniques described herein may be implemented in a number of ways. Example implementations are provided below with reference to the following figures.

Example Semiconductor Device with an Insulating Region in the Backside Structure

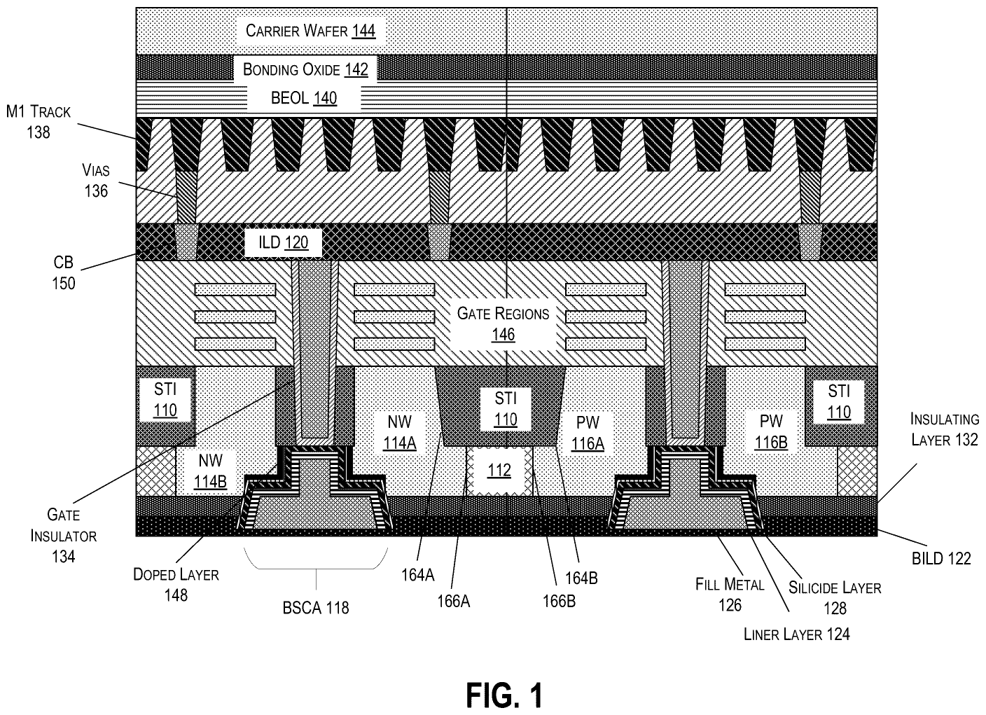

Reference now is made to FIG. 1, which is a simplified cross-section view of a semiconductor device, consistent with an illustrative embodiment. The semiconductor device includes shallow trench isolation, STI 110, an insulating region 112, a first N-well region, NW 114A, a second N-well region, NW 114B, a first P-well region, PW 116A, a second P-well region, PW 116B, a backside contact, BSCA 118, an interlayer dielectric, ILD 120, a bottom ILD, BILD 122, a liner layer 124, a fill metal 126, a silicide layer 128, an insulating layer 132, a gate insulator 134, vias 136, metal lines, M1 track 138, back end of line, BEOL 140, a bonding oxide 142, a carrier wafer 144, gate regions 146, a doped layer 148, and gate contacts, CB 150.

The STI 110 can electrically isolate different components by filling the trenches with an insulating material, such as silicon dioxide. The STI 110 can prevent electrical interference and crosstalk between adjacent devices, ensuring that each component operates independently without affecting its neighbors.

The insulating region 112 can be located below the STI 110. Further, the insulating region 112 is positioned above and directly connected to the conductive layer 130, which, combined with the STI 110A, create a continuous insulating barrier between the NW 114A and PW 116A.

In some embodiments, the width of the insulating region 112 can be smaller than the width of the STI 110. That is, the width of the insulating region 112 is defined by a first end 164A and a second end 164B, while the width of the STI 110 is defined by a third end 166A and a fourth end 166B. Further, the insulating region 112 can be centrally aligned with the STI 110, ensuring symmetry and balance in the design. The distance from the first end 164A to the third end 166A can be substantially equal to the distance from the second end 164B to the fourth end 166B. This equal spacing can facilitate that the insulating region 112 is centered below the STI 110. Such a configuration can allow for effective electrical isolation while optimizing the use of space within the semiconductor device. The reduced width of the insulating region 112 compared to the STI 110 can ensure that the critical pathways remain insulated without unnecessary expansion, enhancing the overall efficiency and performance of the device.

In some embodiments, the width of the insulating region 112 can be smaller than the width of the STI 110. This configuration allows for effective electrical isolation while optimizing the use of space within the semiconductor device. The reduced width of the insulating region 112 compared to the STI 110 can ensure that the critical pathways remain insulated without unnecessary expansion, enhancing the overall efficiency and performance of the device.

The NW 114A and the NW 114B can be doped with the same type of dopant. This consistency in doping type across both well regions can enhance the uniformity of the electric field and improve the device's performance. Conversely, the NW 114A and the NW 114B can be doped with different types of dopants, allowing for the formation of a p-n junction or other semiconductor junction types that are essential for various device functions.

An N-well region and a P-well region can form the p-n junction of the semiconductor device. The p-n junction can control the flow of electrical current within the semiconductor device. The p-n junction can be created by doping two adjacent regions, one with a type P dopant, which introduces an excess of positive charge carriers (holes), and the other with a type N dopant, which introduces an excess of negative charge carriers (electrons). In its natural state, the p-n junction allows current to flow more easily in one direction than in the opposite. When forward biased, i.e., positive voltage applied to the P side relative to the N side, the depletion region narrows, lowering the barrier for charge carriers to move across the junction, and allowing current to flow through the device. Conversely, when reverse-biased, i.e., negative voltage applied to the P side, the depletion region widens, increasing the barrier for charge movement, and significantly reducing the flow of current.

In some embodiments, the NW 114A can be connected to the insulating region 112 and the STI 110 on one side, while the PW 116A can be connected to the insulating region 112 and the STI 110 on the other side. In some embodiments, the insulating region 112 can be surrounded by different well regions.

The BSCA 118 can be a region on the backside of the semiconductor device where electrical connections are made. By establishing the electrical contacts, the BSCA 118 can ensure the proper functioning of the semiconductor device and facilitate electrical signal transmission. The BSCA 118 can serve as a thermal interface between the semiconductor device and a heat sink or other cooling mechanisms. By establishing direct contact with the substrate, the BSCA 118 can conduct the heat away from the semiconductor device, and contribute to improved thermal dissipation. In some embodiments, the BSCA 118 can help mitigate parasitic effects, such as substrate coupling or substrate noise, from the semiconductor device. In further embodiments, the BSCA 118 can allow for increased integration density in the semiconductor device.

The BSCA 118 can include an upper portion 160A, a lower portion 160C, and a middle portion 160B that connects the upper portion 160A and the lower portion 160C. The shape and profile of the insulating region 112 can be identical to the shape and profile of the middle portion 160B.

In some embodiments, the middle portion 160B of the BSCA 118 can be surrounded by two adjacent well regions that are doped with different types of dopants. This arrangement can create a junction that is crucial for the device's functionality, enabling specific electrical characteristics such as improved isolation or controlled conductivity. In some embodiments, the middle portion 160B can be surrounded by two adjacent well regions that are doped with the same type of dopant, which can facilitate achieving uniform electrical properties across the semiconductor device.

The ILD 120 can be a layer of insulating material to electrically isolate and provide mechanical support between different layers of conducting and active components. The ILD 120 can enable efficient signal transmission, reduce crosstalk, and ensure the proper functioning of semiconductor device. In an embodiment, the ILD 120 can electrically isolate adjacent conducting layers or active components. By providing insulation between different layers, the ILD 120 can prevent electrical shorts, reduce (e.g., minimize) leakage current, and ensure that signals are directed only along the desired pathways. In some embodiments, the ILD 120 can help reduce parasitic capacitance between adjacent metal interconnects or active devices and provide mechanical support to the semiconductor device's structure.

In several embodiments, the BILD 122 can provide structural support to the semiconductor device by maintaining the mechanical integrity and stability of the semiconductor device. The BILD 122 can further help prevent the warping, bending, or cracking of the substrate, particularly during the manufacturing process or subsequent handling. The BILD 122 can ensure that the semiconductor device remains mechanically robust and maintains its dimensional stability.

In an embodiment, the BILD 122 can also serve as a planarization layer in the semiconductor device fabrication process. As various layers are deposited and patterned on the front side of the semiconductor device, irregularities or topographic variations may arise. The BILD 122 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 122 can contribute to improved overall semiconductor device performance. In several embodiments, BILD 122 can facilitate wafer-level testing of the semiconductor device. By providing electrical isolation between the active regions and the backside contact, individual semiconductor device or elements on the semiconductor device can be electrically accessed and tested without interference from neighboring devices or components. This enables efficient and accurate wafer-level testing, ensuring quality control during semiconductor manufacturing.

The semiconductor device can include a conductive layer 130 covering the lower portion 160C of the BSCA 118. This conductive layer 130 can establish electrical connectivity between the lower portion 160C and the silicide layer 128. In some embodiments, the fill metal 126 of the lower portion 160C and the conductive layer 130 are made of the same materials. In such embodiments, the liner layer 124 is absent and the fill metal 126 and the conductive layer 130 can be merged. The silicide layer 128 can cover the conductive layer 130, ensuring low resistance and high reliability of the contacts. The doped layer 148, which covers the silicide layer 128, can provide additional functional benefits such as enhanced electrical properties and structural support.

The conductive layer 130 can be a metallic layer, chosen for its conductivity and compatibility with the semiconductor material. The silicide layer 128 can include titanium silicide (TiSix), nickel silicide (NiSix), or cobalt silicide (CoSix). The doped layer 148 can be a silicon germanium (SiGe) layer that is epitaxially grown over the silicide layer 128. This epitaxial growth process can ensure a high-quality crystalline structure that enhance the overall performance of the semiconductor device.

The process of forming the silicide layer 128 can involve metal deposition followed by an annealing step. In such a process, a thin layer of metal, e.g., 2 to 4 nanometers thick, is deposited onto the silicon surface using methods such as chemical vapor deposition (CVD). The metal layer is then subjected to a low-temperature anneal or a laser anneal (nLA), which causes the metal to react with the silicon, forming a stable silicide compound.

The BEOL 140 can include metal interconnects and other structures on the upper layers of the semiconductor device to form a network of connections that link various components of the semiconductor device. The insulating layer 132 can be part of the backside power delivery network (BSPDN) to isolate the semiconductor device. The gate insulator 134 can provide electrical insulation between the gates and the contacts.

The bonding oxide 142 can be a silicon dioxide (SiO2) layer used to provide adhesion between the semiconductor device and the carrier wafer 144. The bonding oxide 142 can be created through oxidation processes such as thermal oxidation or CVD, resulting in a thin, uniform layer of silicon dioxide on the surface of the semiconductor device to ensure that the bonded wafers maintain their structural integrity and electrical isolation.

The carrier wafer 144 can be a temporary support substrate used during various stages of semiconductor fabrication, especially when dealing with thin or fragile wafers to provide mechanical stability and facilitate the handling of delicate wafers through different processing steps, such as thinning, bonding, and dicing. The carrier wafer 144 can be made of a robust material such as silicon, which matches the thermal and mechanical properties of the active wafer to avoid stress and deformation during processing. The carrier wafer 144 can be bonded to the semiconductor device using an adhesive layer, i.e., the bonding oxide 142, and can be removed once the necessary fabrication steps are completed, leaving the processed semiconductor wafer ready for further integration or packaging.

The gate regions 146 serve as control elements that regulate the flow of current through the semiconductor device. The gate regions 146 can be composed of a conductive material. The gate regions 146 can control the flow of electric current across the channel region. In addition to acting as a switch, modulating the gate voltage can enable the gate regions 146 to control the current flowing through the channel region, resulting in amplified output signals.

In an embodiment, the gate regions 146 can enable the implementation of Boolean active operations, such as AND, OR, and NOT, by controlling the flow of current based on the input voltages. In some embodiments, the gate regions 146, along with other active device components, can facilitate the miniaturization and integration of electronic circuits. The ability to control the channel region's conductivity through the gate voltage allows for compact and highly efficient circuit designs.

The CB 150 located over the gate regions 146 can establish connections between the gate regions 146 and the BEOL 140 through the vias 136 and the M1 track 138. The CB 150 can ensure efficient electrical routing and connectivity within the semiconductor device. The fabrication of the CB 150 can involve lithography and etching processes to define the contact area. The CB 150 can be formed on top of the gate channels, and can be made of tungsten (W), aluminum (Al), or polysilicon.

Example Fabrication of Semiconductor Device with an Insulating Region in the Backside

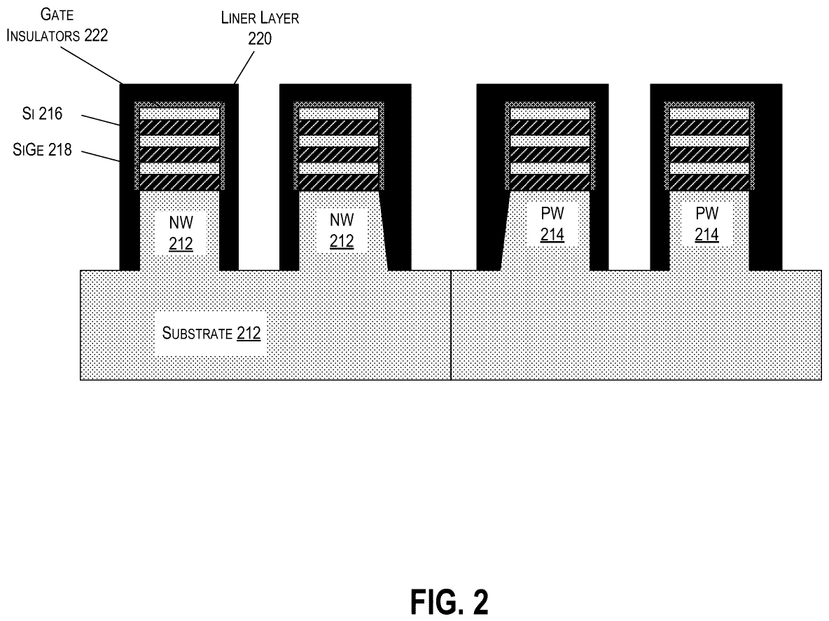

With the foregoing description of an example semiconductor device, it may be helpful to discuss an example process of manufacturing the same. To that end, FIGS. 2-14 illustrate various acts in the manufacture of a semiconductor device, consistent with illustrative embodiments.

Reference now is made to FIG. 2, which is a simplified cross-section view of a semiconductor device after the formation of the liner, consistent with an illustrative embodiment. In some embodiments, the semiconductor device can include a substrate 210, NW 212, PW 214, silicon layers 216, silicon germanium layers 218, a liner layer 220, and gate insulators 222.

In the illustrative example depicted in FIG. 2, the semiconductor device is depicted as being on silicon as the substrate 210, while it will be understood that other types as the substrate 210 can be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate 210 can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

The NW 212 and PW 214 can include portions of the substrate 210 that doped with a dopant. The NW 212 can be doped with N-type dopants and the PW 214 can be doped with—type dopants. The silicon layers 216, and silicon germanium layers 218 can be used to form the channel regions. In some embodiments, portions of the substrate 210 are removed, e.g., etched, to form recesses within the semiconductor device. The liner layer 220 can be formed over sidewalls of the recesses to protect them during the fabrication processes. The gate insulators 222 can be formed over portions of the liner layer 220 that are located over the silicon layer 216 and the silicon germanium layer 218.

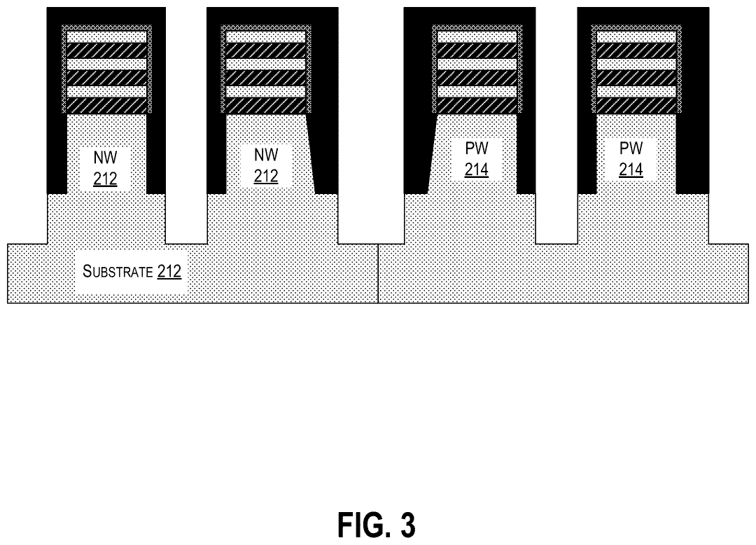

FIG. 3 illustrates a semiconductor device after the etching of the substrate, in accordance with some embodiments. In some embodiments, an organic planarization layer, the exposed portions of the substrate 210 between the recesses are etched.

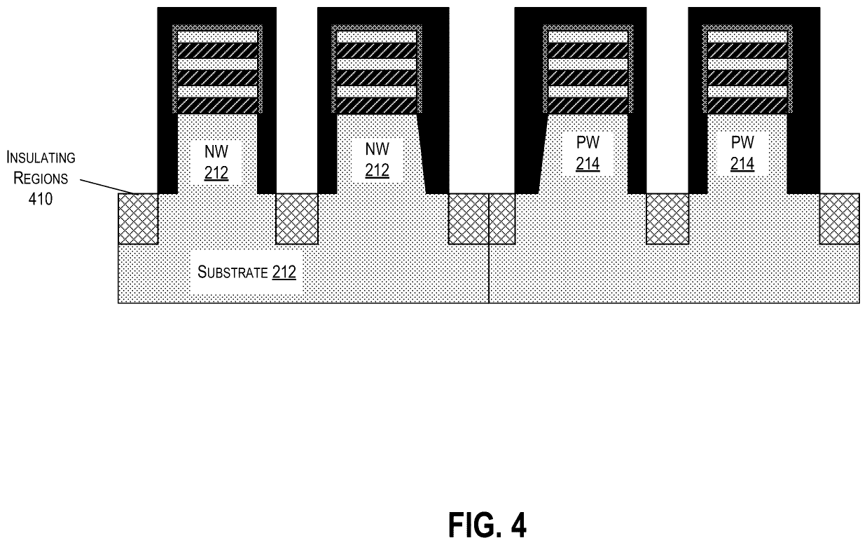

FIG. 4 illustrates a semiconductor device after the filling the etched portions of the substrate, in accordance with some embodiments. In some embodiments, the etched portions of the substrate are filled to form insulating region 410. In some embodiments, a pinch off followed by a recession process can be formed. Alternatively, in some embodiments, a plane fill followed by a recession are performed.

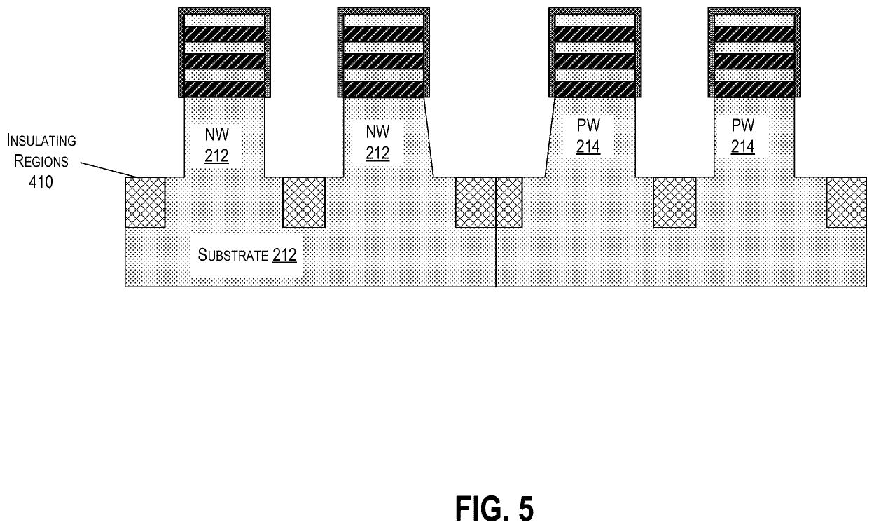

FIG. 5 illustrates a semiconductor device after the removal of the liner layer, in accordance with some embodiments. In some embodiments, the liner layer is removed from the semiconductor device to expose the insulating region 410, the gate insulators 222, and portions of the NW 212 and PW 214.

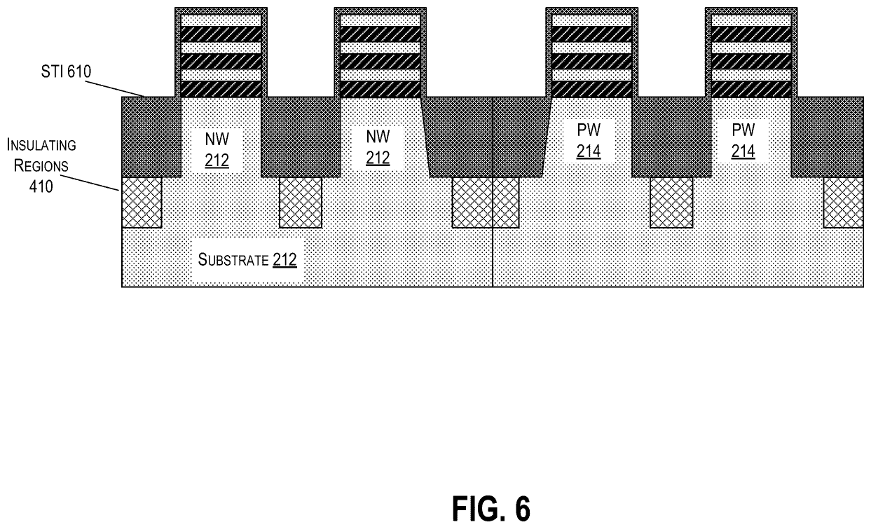

FIG. 6 illustrates a semiconductor device after the formation of the shallow trench isolation, in accordance with some embodiments. In some embodiments, the STI 610 is formed between the recesses. In some embodiments, the STI 610 and the gate insulators 222 can be made from the same materials.

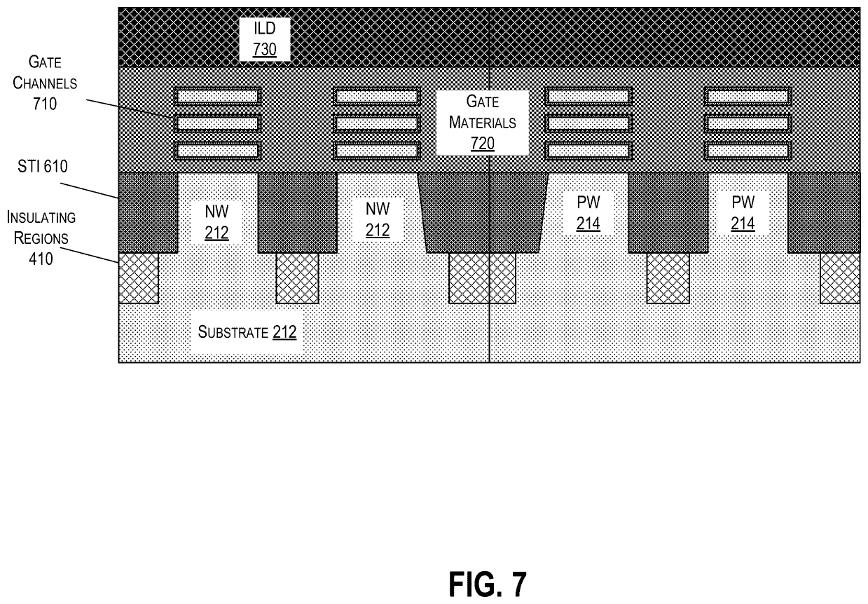

FIG. 7 illustrates a semiconductor device after the formation of the gates, in accordance with some embodiments. In some embodiments, gate channels 710, gate materials 720 and interlayer dielectric, ILD 730 are formed over the semiconductor device to form the gates.

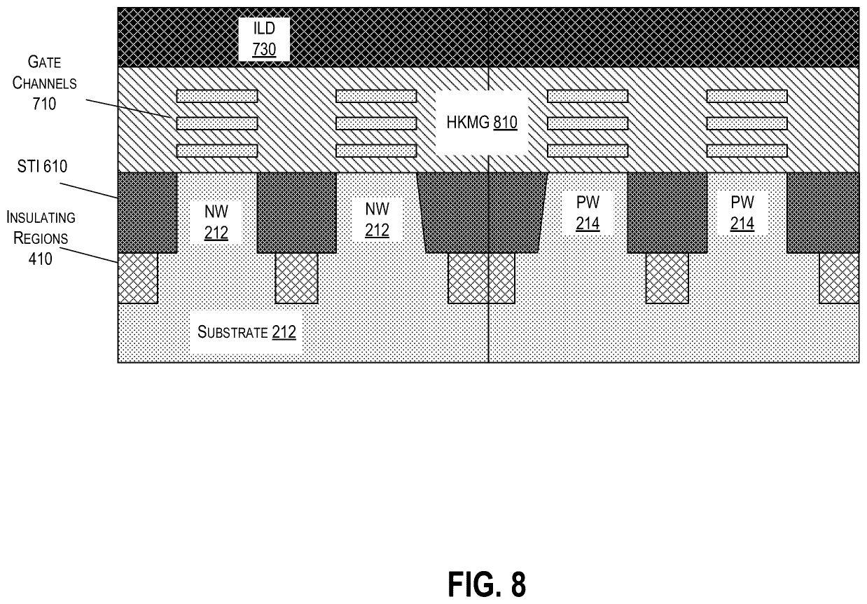

FIG. 8 illustrates a semiconductor device after the metallization of the gate regions, in accordance with some embodiments. In some embodiments, a replacement metal gate (RMG) process can be used to fabricate metal gate electrodes. RMG can involve the replacement of the SiGe with a metal material, i.e., HKMG 810, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability.

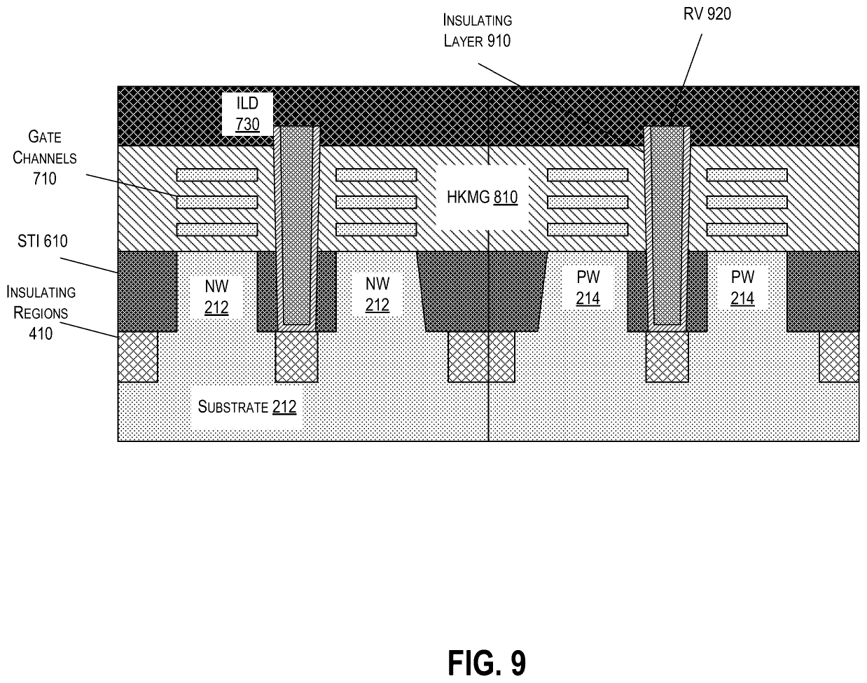

FIG. 9 illustrates a semiconductor device after the filling the frontside via, in accordance with some embodiments. In some embodiments, portions of the HKMG 810 and the STI 510 between the gate channels 710 are removed. Subsequently, an insulating layer 910 is formed over sidewalls of the recessed portions. The remaining portions of the recesses can be filled with a suitable material to form the frontside via, RV 920. The RV 920 can be formed using a reactive ion etching (RIE). Generally, RIE is a dry etching process used in semiconductor device fabrication to remove materials from the surface of a substrate selectively. In some embodiments, RIE can involve the use of reactive ions and plasma to react with and remove specific materials chemically. In an embodiment, the RIE process begins by placing the semiconductor device inside a vacuum chamber. The chamber is then evacuated to create a low-pressure environment. Reactive gases, which can include a combination of a chemically reactive gas and an inert gas, are introduced into the chamber. The chemically reactive gas, such as fluorine-based gases (e.g., CF4, SF6) or chlorine-based gases (e.g., Cl2), can react with the material to be etched, i.e., the second substrate, Si, while the inert gas, e.g., argon, can help to control the ion bombardment.

In some embodiments, radiofrequency or microwave power is applied to create a plasma within the chamber. In such embodiments, power excites the gas molecules, causing them to ionize and form a plasma of reactive ions and electrons. The plasma can include reactive ions that chemically react with the silicon. The reactive ions bombard the substrate surface, break chemical bonds and remove silicon. In various embodiments, the RIE process can be selective, meaning it can mainly affect the target material, i.e., silicon, while leaving other materials, such as masking layers or underlying layers, relatively unaffected.

In some embodiments, to achieve selective etching, an etch mask can be applied on the substrate surface prior to the RIE process. The etch mask protects certain regions from etching, allowing the reactive ions to remove the exposed material selectively. The etching process can be controlled to achieve specific etch profiles, such as vertical sidewalls or tapered structures. Parameters such as gas composition, pressure, power, and process duration are adjusted to achieve the desired etch characteristics. In some embodiments, endpoint detection techniques, such as optical emission spectroscopy or laser interferometry, can be used to determine when the etching process has reached a desired endpoint. This ensures accurate control of the etch depth and prevents over-etching. After the etching process is completed, the substrate can be cleaned to remove any residue or by-products from the etching. Cleaning can involve rinsing with solvents or plasma cleaning to ensure the substrate's surface is free from contaminants.

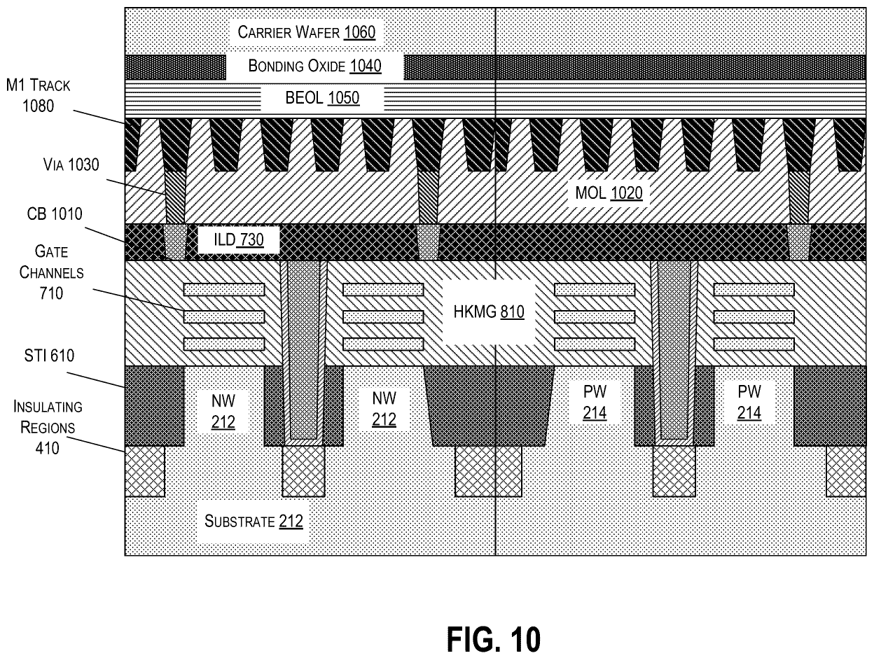

FIG. 10 illustrates a semiconductor device after the back end of line processes, in accordance with some embodiments. In some embodiments, the gate contacts, CB 1010 are patterned and formed within the ILD 730. A middle of line, MOL 1020, is formed over the ILD 730 which can include vias 1030 and M1 track 1080. A back end of line, BEOL 1050 is formed over the MOL 1020 followed by the formation of the bonding oxide 1060 and the carrier wafer 1070.

In some embodiments, carrier wafer 1070 bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices.

The formation of the bonding oxide 1040 in semiconductor fabrication involves creating a thin layer of silicon dioxide (SiO₂) on the surface of a silicon wafer. This oxide layer can provide adhesion between different wafers or layers and provides excellent electrical insulation. The silicon wafer surface can be thoroughly cleaned to remove contaminants, organic residues, or native oxides that could interfere with the formation of a uniform bonding oxide. This cleaning process often involves a series of chemical treatments, including the use of solutions such as hydrogen peroxide (H₂O₂), sulfuric acid (H₂SO₄), and hydrofluoric acid (HF), followed by a deionized water rinse. The cleaned silicon wafer is then subjected to a thermal oxidation process to grow the silicon dioxide layer. The wafer is placed in a high-temperature furnace, typically at temperatures ranging from 900° C. to 1100° C. The furnace atmosphere is composed of either dry oxygen (O₂) or a mixture of oxygen and steam (H₂O), depending on whether dry or wet oxidation is desired. In dry oxidation, the silicon reacts with oxygen to form silicon dioxide. In wet oxidation, steam is used to facilitate the oxidation process, resulting in a faster growth rate of the oxide layer. The thickness of the bonding oxide 1040 can be controlled by adjusting the oxidation time and temperature. For bonding purposes, the oxide layer can range from a few nanometers to several micrometers in thickness. Thicker oxide layers provide better insulation and mechanical strength, while thinner layers offer lower electrical resistance and better interface properties.

After the oxidation process, the wafer can undergo an annealing step to improve the quality and stability of the silicon dioxide layer. Annealing is performed at high temperatures in an inert atmosphere, such as nitrogen (N₂) or argon (Ar). This step helps to reduce defects in the oxide layer, such as interface traps and fixed charges, and enhances the overall bonding strength between the oxide and the silicon substrate. In some cases, CVD is used to form the bonding oxide 1040 instead of thermal oxidation. In the CVD process, gaseous precursors, such as silane (SiH₄) and oxygen (O₂), react in a controlled environment to deposit a uniform layer of silicon dioxide on the wafer surface.

Before bonding, the oxide surface may undergo additional conditioning to enhance its hydrophilicity and ensure proper adhesion. This step can involve treating the oxide surface with an aqueous solution, such as a mixture of hydrogen peroxide and ammonia (NH₄OH), to create a hydrophilic surface that facilitates strong bonding. Once the bonding oxide layer is formed and conditioned, the wafers can be aligned and bonded together using various techniques, such as direct wafer bonding or adhesive bonding.

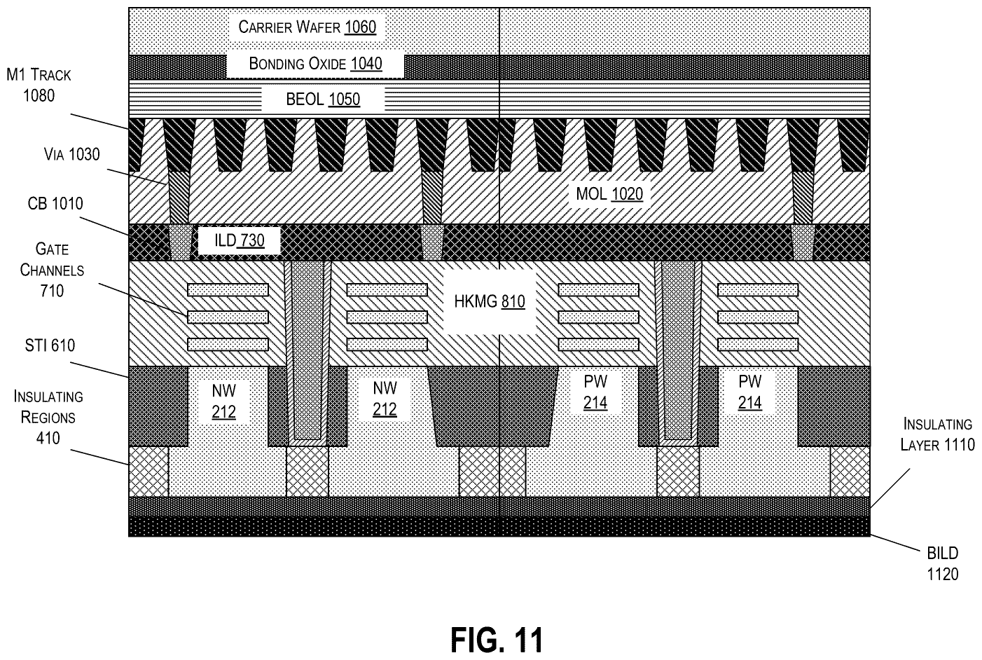

FIG. 11 illustrates the semiconductor device after the recession of the substrate, in accordance with some embodiments. In some embodiments, the substrate is removed from the bottom of the semiconductor device to expose the NW 212, the PW 214 and the insulating region 410. An insulating layer 1110 can be formed over the exposed the NW 212, the PW 214 and the insulating region 410 is formed followed by forming a bottom ILD, BILD 1120.

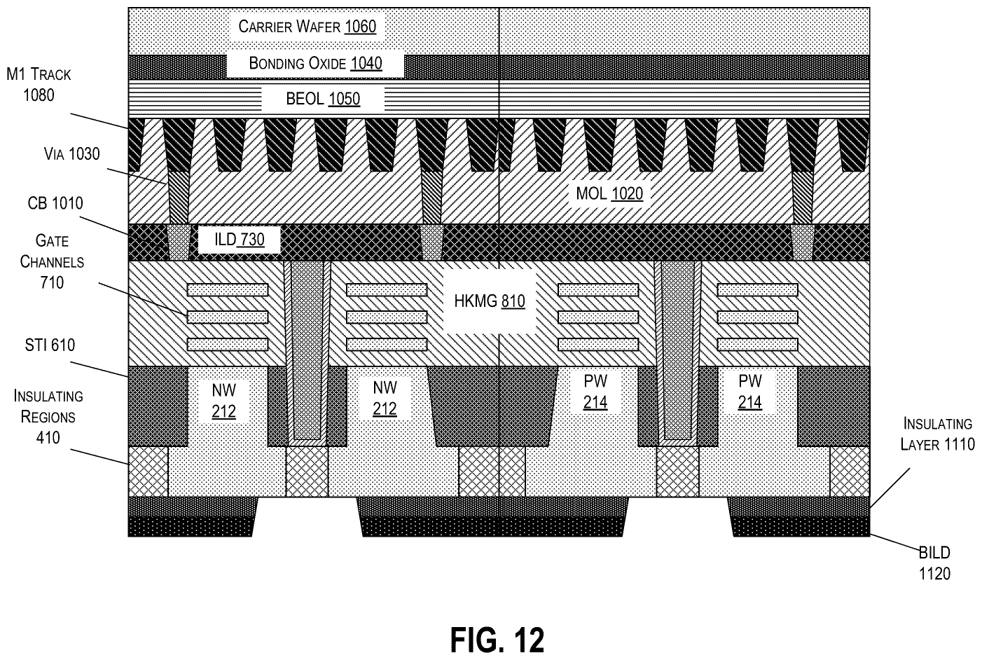

FIG. 12 illustrates the semiconductor device after the etching the insulating layer and the BILD 1120, in accordance with some embodiments. In some embodiments, portions of the BILD 1120 he backside contacts.

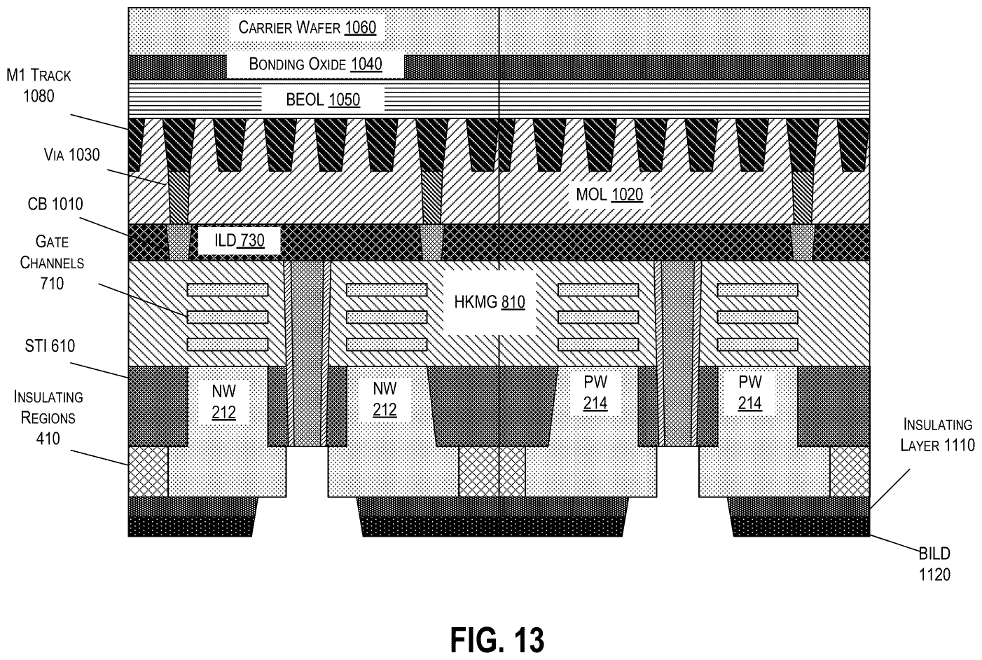

FIG. 13 illustrates a semiconductor device after the removal of the insulating regions, in accordance with some embodiments. In some embodiments, the insulating regions below the RV 920 are removed. The removed insulating regions can be used to form the backside contacts.

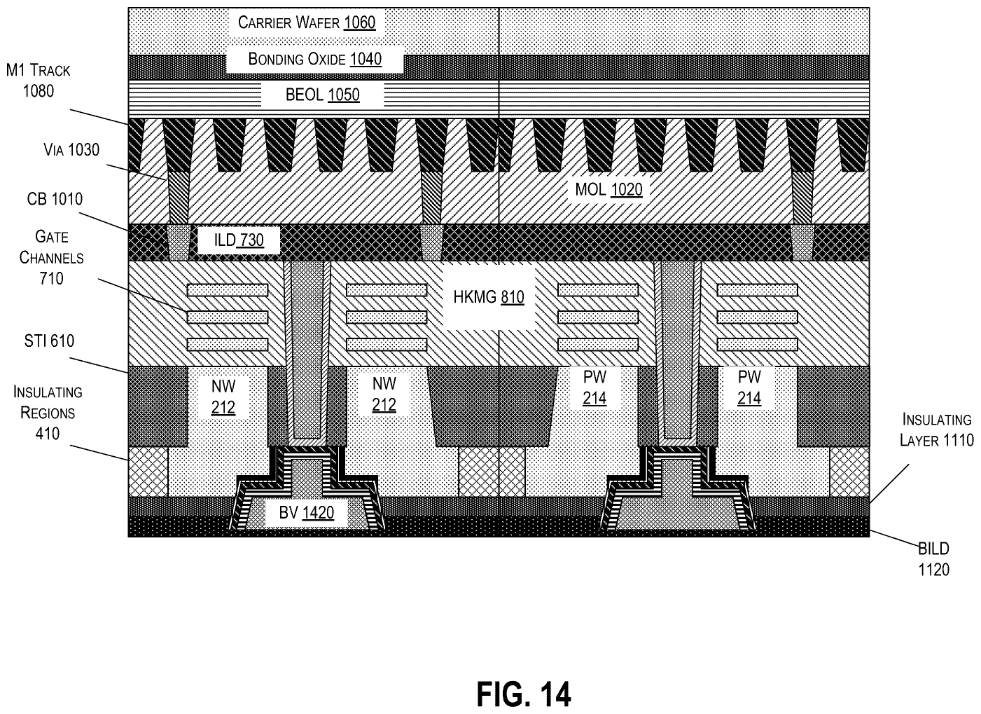

FIG. 14 illustrates a semiconductor device after the formation of the backside contact, in accordance with some embodiments. In some embodiments, the recesses are filled with suitable materials to form the middle portion of the backside contact and the lower portion, BV 1420, of the backside contact.

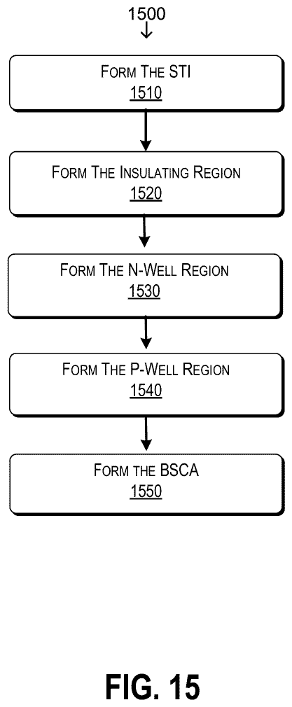

FIG. 15 illustrates a block diagram of a method 1500 for forming the semiconductor device, in accordance with some embodiments. As shown by block 1510, STI is formed.

As shown by block 1520, the insulating region is formed.

As shown by block 1530, the N-well region is formed. The N-well region is connected to the insulating region and the STI on a first side.

As shown by block 1540, the P-well region is formed. The P-well region is connected to the insulating region and the STI on the second side.

As shown by block 1550, backside contact is formed.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a shallow trench isolation (STI);
an insulating region below the STI;
a first well region connected to the insulating region and the STI on a first side;
a second well region connected to the insulating region and the STI on a second side; and
a backside contact comprising an upper portion, a lower portion, and a middle portion connecting the upper portion and the lower portion,
wherein a shape and a profile of the insulating region is same as a shape and a profile of the middle portion.

2. The semiconductor device of claim 1, wherein a width of the insulating region is smaller than a width of the STI.

3. The semiconductor device of claim 1, further comprising an insulating layer horizontally extended below the semiconductor device, wherein the insulating region is above and directly connected to the insulating layer.

4. The semiconductor device of claim 1, wherein:
a width of the STI has a first end and a second end,
a width of the insulating region has a third end and a fourth end,
the insulating region is centrally aligned with the STI, and
a first distance from the first end to the third end is equal to a second distance from the second end to the fourth end.

5. The semiconductor device of claim 1, wherein the middle portion is surrounded by two adjacent well regions doped with different types of dopants.

6. The semiconductor device of claim 1, wherein the middle portion is surrounded by two adjacent well regions doped with a same type of dopant.

7. The semiconductor device of claim 1, wherein the first well region and the second well region are doped with a same type of dopant.

8. The semiconductor device of claim 1, wherein the first well region and the second well region are doped with different types of dopants.

9. The semiconductor device of claim 1, further comprising:
a conductive layer covering the lower portion;
a silicide layer covering the conductive layer; and
a doped layer covering the silicide layer.

10. The semiconductor device of claim 9, wherein:
the conductive layer is a metal layer,
the silicide layer includes at least one of: a titanium silicide layer, a nickel silicide layer, and a cobalt silicide layer, and
the doped layer includes a silicon germanium layer epitaxially grown over the silicide layer.

11. The semiconductor device of claim 9, further comprising a liner layer between the lower portion and the conductive layer, wherein the liner layer includes titanium nitride.

12. A method for fabrication of a semiconductor device, the method comprising:
forming a shallow trench isolation (STI);
forming an insulating region below the STI;
forming a first well region connected to the insulating region and the STI on a first side;
forming a second well region connected to the insulating region and the STI on a second side; and
forming a backside contact comprising an upper portion, a lower portion, and a middle portion connecting the upper portion and the lower portion,
wherein a shape and a profile of the insulating region is same as a shape and a profile of the middle portion.

13. The method of claim 12, further comprising:
forming an insulating layer horizontally extended below the semiconductor device; and
establishing a direct connection between the insulating region and the insulating layer.

14. The method of claim 12, further comprising surrounding the middle portion by two adjacent well regions doped with different types of dopants.

15. The method of claim 12, further comprising surrounding the middle portion by two adjacent well regions doped with a same type of dopant.

16. The method of claim 12, further comprising doping he first well region and the second well region with a same type of dopant.

17. The method of claim 12, further comprising doping the first well region and the second well region with different types of dopants.

18. The method of claim 12, further comprising:
forming a conductive layer covering the lower portion;
forming a silicide layer covering the conductive layer; and
forming a doped layer covering the silicide layer.

19. The method of claim 18, further comprising forming a liner layer between the lower portion and the conductive layer.

20. A semiconductor device, comprising:
a shallow trench isolation (STI);
an insulating region below the STI;
a first well region connected to the insulating region and the STI on a first side;
a second well region connected to the insulating region and the STI on a second side; and
an insulating layer horizontally extended below and directly connected to the insulating layer, wherein:
a width of the STI has a first end and a second end,
a width of the insulating region has a third end and a fourth end,
the insulating region is centrally aligned with the STI, and
a first distance from the first end to the third end is equal to a second distance from the second end to the fourth end.

21. The semiconductor device of claim 20, further comprising:
a backside contact comprising an upper portion, a lower portion, and a middle portion connecting the upper portion and the lower portion,
wherein a shape and a profile of the insulating region is same as a shape and a profile of the middle portion.

22. The semiconductor device of claim 21, further comprising:
a conductive layer covering the lower portion;
a silicide layer covering the conductive layer; and
a doped layer covering the silicide layer.

23. The semiconductor device of claim 22, wherein:
the conductive layer is a metallic layer,
the silicide layer includes at least one of: a titanium silicide layer, a nickel silicide layer, and a cobalt silicide layer, and
the doped layer includes a silicon germanium layer epitaxially grown over the silicide layer.

24. The semiconductor device of claim 22, further comprising a liner layer between the lower portion and the conductive layer, wherein the liner layer includes titanium nitride.

25. The semiconductor device of claim 23, wherein the conductive layer is made of a same material as the lower portion.
